(19) United States
(12) Patent Application Publication
(10) Pub. No.: US 2021/0408354 A1
(43) Pub. Date: Dec. 30, 2021

(54) QUANTUM DEVICE

(71) Applicant: NEC Corporation, Tokyo (JP)

(72) Inventors: Katsumi KIKUCHI, Tokyo (JP); Akira MIYATA, Tokyo (JP); Suguru WATANABE, Tokyo (JP); Takanori NISHI, Tokyo (JP); Hideyuki SATOU, Tokyo (JP); Kenji NANBA, Tokyo (JP); Ayami YAMAGUCHI, Tokyo (JP)

(73) Assignee: NEC Corporation, Tokyo (JP)

(21) Appl. No.: 17/357,094

(22) Filed: Jun. 24, 2021

(30) Foreign Application Priority Data
Jun. 29, 2020 (JP) 2020-111952

(51) Int. Cl. H01L 39/04

(52) U.S. Cl. CPC H01L 39/04

(57) ABSTRACT

To provide a quantum device capable of preventing a connection member connecting a quantum chip with an interposer from being broken. The quantum device 1 includes at least one quantum chip 10, at least one interposer 20 on which the at least one quantum chip 10 is mounted, and a plurality of connection members 30 formed of a conductor. The plurality of connection members 30 are disposed between the quantum chip 10 and the interposer 20, and connect the quantum chip 10 with the interposer 20. The size of the connection member 30 on the surface along the mounting surface 20s of the interposer 20 is changed according to the position thereof relative to the quantum chip 10.

### INCORPORATION BY REFERENCE

This application is based upon and claims the benefit of priority from Japanese patent application No. 2020-111952, filed on Jun. 29, 2020, the disclosure of which is incorporated herein in its entirety by reference.

### TECHNICAL FIELD

The present disclosure relates to a quantum device.

### BACKGROUND ART

Published Japanese Translation of PCT International Publication for Patent Application, No. 2019-504511 discloses a device including a first chip joined (e.g., bonded) to a second chip by superconducting bump bonding. Further, Published Japanese Translation of PCT International Publication for Patent Application, No. 2019-537239 discloses a quantum computing assembly (a quantum computing device) in which a quantum-device die for generating a plurality of qubits and a control-circuit die for controlling the operation of the quantum-device die are disposed on a substrate. The quantum-device die and the substrate are connected to each other by solder bumps or the like. The quantum computing device may include a cooling unit.

A quantum device (a quantum computer) using a quantum chip operates while being cooled to an extremely low temperature of about 10 mK (milli-Kelvin; absolute temperature). In such a case, when the quantum chip and the interposer are cooled, the components constituting the quantum device contract and are thereby deformed. Therefore, in the above-described patent literatures, there is a risk that, when the quantum device is cooled, a connection member that connects the quantum chip with the interposer may be broken.

The present disclosure has been made to solve the above-described problem, and an object thereof is to provide a quantum device capable of preventing a connection member connecting a quantum chip with an interposer from being broken.

### SUMMARY

In a first example aspect, a quantum device includes: at least one quantum chip in which a quantum bit is formed; and at least one interposer in which at least one quantum chip is mounted; and a plurality of connection members each of which is formed of a conductor, the plurality of connection members being disposed between the quantum chip and the interposer so as to connect the quantum chip with the interposer, in which a size of each of the plurality of connection members on a surface along a mounting surface of the interposer is changed according to a position of that connection member relative to the quantum chip, the mounting surface being a surface on which the quantum chip is mounted.

According to the present disclosure, it is possible to provide a quantum device capable of preventing a connection member connecting a quantum chip with an interposer from being broken.

### BRIEF DESCRIPTION OF DRAWINGS

The above and other aspects, features and advantages of the present disclosure will become more apparent from the following description of certain example embodiments when taken in conjunction with the accompanying drawings, in which:

FIG. 1 shows an overview of a quantum device according to this example embodiment;

FIG. 2 shows a configuration of a quantum device according to a comparative example;

FIG. 3 is a plan view showing a quantum device according to a first example embodiment;

FIG. 4 is a plan view showing a quantum device according to a second example embodiment;

FIG. 5 is a plan view showing a quantum device according to a third example embodiment;

FIG. 6 is a plan view showing a quantum device according to a fourth example embodiment;

FIG. 7 shows an example of a connection member disposed near a corner of a quantum chip according to a first modified example;

FIG. 8 shows an example of a shape of an XY-plane of a connection member according to a second modified example;

FIG. 9 schematically shows a relation between the orientations of connection members and the position of a quantum chip according to the second modified example;

FIG. 10 is a plan view showing a quantum device according to a fifth example embodiment;

FIG. 11 is a plan view showing a quantum device according to a sixth example embodiment;

FIG. 12 is a plan view showing a quantum device according to a seventh example embodiment; and

FIG. 13 is a plan view showing a quantum chip according to an eighth example embodiment.

### EXAMPLE EMBODIMENTS

### Overview of Example Embodiment According to Present Disclosure

Quantum computing is a technical field in which data is manipulated by using a quantum mechanical phenomenon (a quantum bit). Further, the quantum mechanical phenomenon is, for example, superposition of a plurality of states (i.e., a quantum variable simultaneously assumes a plurality of different states) or entanglement (i.e., a state in which a plurality of quantum variables are related to each other regardless of space or time). In a quantum chip (which will be described later), a quantum circuit that generates a quantum bit is provided.

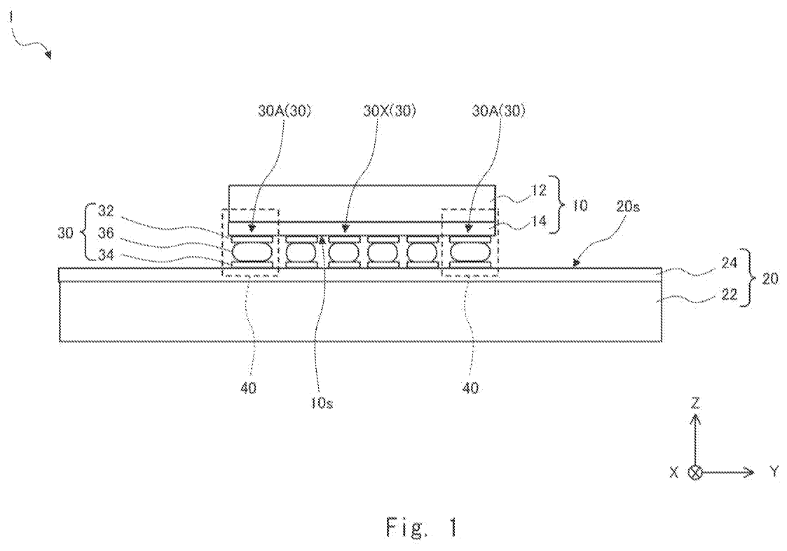

Prior to a description of an example embodiment according to the present disclosure, an overview of the example embodiment according to the present disclosure will be described hereinafter. FIG. 1 shows an overview of a quantum device 1 according to this example embodiment. FIG. 1 is a side view (a cross-sectional view) of the quantum device 1 according to this example embodiment.

As shown in FIG. 1, the quantum device 1 includes a quantum chip 10, an interposer 20 on which at least one quantum chip 10 is mounted, and a plurality of connection members 30. The quantum chip 10 includes a quantum circuit (not shown) such as a resonator (a loop circuit and a conductive member connected to the loop circuit). The quantum circuit performs processing by using the resonator in a superconducting state in which the quantum chip is in a quantum state. As described above, the quantum chip 10 includes the quantum circuit and performs processing under the quantum state (i.e., by using the quantum mechanical phenomenon). That is, a quantum computer can be constructed by using such a quantum device 1 (a quantum chip 10).

Note that although a silicon substrate is used as a quantum-chip substrate 12, an interposer substrate 22, and like in this example embodiment, the material for the substrates is not limited to silicon. For example, a sapphire substrate, a compound semiconductor substrate (Groups IV, III-V, and II-VI), or a glass substrate may be used as the aforementioned substrate. These materials are preferably single-crystalline materials, but they may be polycrystalline materials or amorphous materials.

Further, in this example embodiment, the superconducting material is a material that becomes superconductive at an extremely low temperature (about 10 mK) as described later. Further, the non-superconducting (i.e., normal conducting) material is a material that does not become superconductive in any temperature range as described later. Further, in this example embodiment, the superconducting material is, for example, niobium (Nb), niobium nitride, aluminum (Al), indium (In), lead (Pb), tin (Sn), rhenium (Re), palladium (Pd), titanium (Ti), titanium nitride, tantalum (Ta), or an alloy containing at least one of them. Further, in this example embodiment, the non-superconducting material is, for example, copper (Cu), silver (Ag), gold (Au), platinum (Pt), or an alloy containing at least one of them. Note that, in order to obtain a superconducting state, the quantum device 1 is used in an environment having a temperature of, for example, about 10 mK (milli-Kelvin) that is obtained by using a refrigerator (or a freezer).

The quantum chip 10 includes a quantum-chip substrate 12 and a quantum-chip wiring layer 14. As described above, the quantum-chip substrate 12 is formed of, for example, a silicon substrate. The quantum-chip wiring layer 14 is formed of a superconducting material such as niobium (Nb) as described above. The quantum-chip wiring layer 14 is disposed on a surface of the quantum-chip substrate 12 on the side thereof on which the interposer 20 is located. The above-described quantum circuit is formed in the quantum-chip wiring layer 14. Further, circuit for a ground electrode (hereinafter also referred to as a ground electrode circuit) may be formed in the quantum-chip wiring layer 14. Further, in the above-described quantum circuit, aluminum (Al) is preferably used as the material used for the Josephson junction, but other superconducting materials may be used as the material used for the Josephson junction.

The interposer 20 includes an interposer substrate 22 and an interposer wiring layer 24. The interposer wiring layer 24 is disposed on a surface of the interposer substrate 22 on the side thereof on which the quantum chip 10 located. As described above, the interposer substrate 22 is formed of, for example, a silicon substrate. Further, the surface of the interposer substrate 22 is preferably covered by a silicon oxide film (such as a SiO₂ film or a TEOS film). The interposer wiring layer 24 may be formed of, for example, a superconducting material such as niobium (Nb) as described above. In such a case, the interposer wiring layer 24 may contain the same superconducting material as that contained in the quantum-chip wiring layer 14, and/or a superconducting material different from that contained in the quantum-chip wiring layer 14. Further, the interposer wiring layer 24 may contain a non-superconducting material such as copper (Cu) as described above. For example, the interposer wiring layer 24 preferably includes an Nb layer (having a thickness of 0.1 [μm]) in the surface, includes a Cu layer (having a thickness of 2 [μm]) under the Nb layer, and includes a Ti layer under the Cu layer. For example, when the interposer substrate 22 contains silicon, the surface of the interposer 20 on the side thereof on which the quantum chip 10 is located is preferably has a structure expressed as Nb/Cu/Ti/SiO₂/Si (the interposer substrate 22).

A quantum circuit may be formed in the interposer wiring layer 24. For example, a magnetic-field applying circuit (not shown) that applies a magnetic field to a resonator (a loop circuit) may be formed in the interposer wiring layer 24. Further, a reading circuit (not shown) that reads information about a quantum state from the resonator (a conductive member) may be formed in the interposer wiring layer 24. Further, a ground electrode circuit may be formed in the interposer wiring layer 24. That is, a ground electrode circuit may be formed as a quantum circuit in the interposer wiring layer 24. In the case where a quantum circuit is formed in the interposer wiring layer 24 as described above, the interposer 20 functions as a quantum interposer. Further, an oscillator (not shown) may be formed by at least the resonator and the magnetic-field applying circuit.

Further, the quantum chip 10 is mounted on the interposer 20. For example, the quantum chip 10 is connected to the interposer 20 by using a flip-chip connecting technique (hereinafter also expressed as being flip-chip connected). Further, the quantum chip 10 is connected to the interposer 20 with the plurality of connection members 30 interposed therebetween. Further, no sealing material such as an underfill agent is formed around the connection members 30 interposed between the quantum chip 10 and the interposer 20. Therefore, the area around the connection members 30 interposed between the quantum chip 10 and the interposer 20 is a space (i.e., a void).

Each of the connection members 30 is formed of a conductor. Although the connection member 30 is formed of, for example, a superconducting material like the one described above, it may contain a non-superconducting material. The plurality of connection members 30 are provided (i.e., interposed) between the quantum chip 10 and the interposer 20 so as to connect the quantum chip 10 with the interposer 20. Each of the connection members 30 is composed of a connection terminal 32 (a first connection terminal), a connection terminal 34 (a second connection terminal), and a bump 36. The connection terminal 32 is formed in the quantum chip 10 (in the quantum-chip wiring layer 14). The connection terminal 32 is also called an electrode or a pad in the quantum chip 10. Further, the connection terminal 34 is formed in the interposer 20 (in the interposer wiring layer 24). The connection terminal 34 is also called an electrode or a pad in the interposer 20.

Further, the bump 36 connects the connection terminal 32 with the connection terminal 34. In other words, the quantum-chip wiring layer 14 is connected to the interposer wiring layer 24 through the bumps 36. In this way, the quantum chip 10 is flip-chip connected to the interposer 20.

Note that the connection terminals 32 and 34, and the bumps 36 do not have to be made of the same material as each other. Further, the connection terminal 32 may be formed of the same material as that of the quantum-chip wiring layer 14. In such a case, the connection terminal 32 may be formed integrally with the quantum-chip wiring layer 14. Further, the connection terminal 34 may be formed of the same material as that of the interposer wiring layer 24. In such a case, the connection terminal 34 may be formed integrally with the interposer wiring layer 24.

Note that the bumps 36 may transmit signals therethrough between the quantum-chip wiring layer 14 and the interposer wiring layer 24. For example, the bump 36 may connect the part of the quantum-chip wiring layer 14 in which the ground electrode circuit is formed to the part of the interposer wiring layer 24 in which the ground electrode circuit is formed. In this way, the potentials in these ground electrodes can be equal to each other. In such a case, the bumps 36 may include a superconducting material and a non-superconducting material. That is, each of the bumps 36 may have a multilayer structure. Further, the flip-chip connection preferably has a layered structure expressed as Nb (the wiring lines of the quantum chip 10 (the connection terminals 32))/In/Ti/Nb (the wiring surface of the interposer 20 (the connection terminals 34))/Cu. Alternatively, the flip-chip connection preferably has a layered structure expressed as Nb (the wiring lines of the quantum chip 10 (the connection terminals 32))/Nb (the wiring surface of the interposer 20 (the connection terminals 34))/Cu. Further, copper (Cu) may be added to an interposer wiring layer 24 having a thickness of 2 [μm] in a range of thickness from 2 [μm] to 10 [μm], and bumps 36 each of which has a diameter of 100 [μm] may be provided therein.

Note that an XYZ-orthogonal coordinate system is used for facilitating the explanation of the quantum device 1. A plane (i.e., a surface) along a mounting surface 20s, of the interposer 20, on which the quantum chip 10 is mounted is defined as an XY-plane, and a direction perpendicular to the mounting surface 20s is defined as a Z-axis direction. The Z-axis positive direction is referred to as an upward direction and the Z-axis negative direction is referred to as a downward direction. Note that the terms “upward” and “downward” are used just for the explanatory purpose, and do not indicate the directions in which the actual quantum device 1 is positioned when it is used. Further, the position of the origin of the XYZ-orthogonal coordinate system is arbitrarily determined. Further, the direction along the XY-plane corresponds to the lateral direction (the horizontal direction) in FIG. 1. Further, the Z-axis direction corresponds to the longitudinal direction (the vertical direction) in FIG. 1, and is the direction in which the quantum chip 10 and the interposer 20 are connected to each other. Further, the mounting surface 20s is a surface of the interposer 20 that is opposed to the quantum chip 10 (i.e., the opposing surface of the interposer 20). Further, it can be considered that the XY-plane extends along the mounting surface 10s of the quantum chip 10 that is opposed to the interposer 20 when the quantum chip 10 is mounted on the interposer 20. In such a case, in this example embodiment, the size of each of the plurality of connection members 30 on the surface along the XY-plane (the size that is defined on the surface along the mounting surface 20s (along the mounting surface 10s)) is changed according to the position of that connection member relative to the quantum chip 10. Here, an outer-peripheral area 40 corresponding to the outer periphery of the quantum chip 10 is defined. For example, in the example shown in FIG. 1, the size of a connection member(s) 30A, which is connected to at least a part of the outer-peripheral area 40, on the surface along the XY-plane is larger than the size of a connection member(s) 30X, which is connected to an area other than the outer-peripheral area 40 of the quantum chip 10, on the surface along the XY-plane. Note that, in the following description, “the plane (i.e., the surface) along the XY-plane” is simply referred to as the “XY-plane”. That is, in this example embodiment, the “XY Plane” does not mean a plane whose Z-axis value is zero (Z=0), but does mean any plane perpendicular to the Z-axis. That is, the “XY Plane” is an arbitrary plane at any position on the Z-axis. Further, the “size on the plane (i.e., the surface) along the XY-plane” is simply referred to as the “size on the XY-plane”. For example, the size of the connection member(s) 30A connected to the outer-peripheral area 40 on the XY-plane is 1.1 to 4 times the size of the connection member(s) 30X connected to an area other than the outer-peripheral area 40 of the quantum chip 10. The size of the connection member(s) 30A connected to the outer-peripheral area 40 on the XY-plane is preferably 1.1 to 2 times the size of the connection member(s) 30X connected to an area other than the outer-peripheral area 40 of the quantum chip 10.

Note that, in this example embodiment, the “size of the connection member 30 on the XY-plane” may be, for example, the size of the cross section of the bump 36 on the XY-plane. Alternatively, the “size of the connection member 30 on the XY-plane” may be, for example, the size of the connection terminal 32 or 34 on the XY-plane. Further, the “size of the connection member 30 on the XY-plane” may be, for example, the size of the cross section of the connection member 30 on the XY-plane or the maximum diameter of the connection member 30 on the XY-plane. For example, when the connection member 30 has its longitudinal direction on the XY-plane, the “size of the connection member 30 on the XY-plane” may be the length of the connection member 30 in the longitudinal direction on the XY-plane. Alternatively, the “size of the connection member 30 on the XY-plane” may be the length of the outer circumference of the connection member 30 on the XY-plane. Therefore, the “size of the connection member 30 on the XY-plane” may be, for example, the size of the cross section of the bump 36 on the XY-plane (or the length in the longitudinal direction or the length of the outer circumference of the bump 36 on the XY-plane). Alternatively, the “size of the connection member 30 on the XY-plane” may be, for example, the size of the cross section of the connection terminal 32 on the XY-plane (or the length in the longitudinal direction or the length of the outer circumference of the connection terminal 32 on the XY-plane). Alternatively, the “size of the connection member 30 on the XY-plane” may be, for example, the size of the cross section of the connection terminal 34 on the XY-plane (or the length in the longitudinal direction or the length of the outer circumference of the connection terminal 34 on the XY-plane). As described above, it is possible to arbitrarily select, as the “size of the connection member 30 on the XY-plane”, the size of an arbitrary component included in the connection member 30 (the connection terminal 32, the connection terminal 34, or the bump 36) or a parameter related to the size (the size of the cross section, the length in the longitudinal direction, or the length of the outer circumference) in the connection member 30. However, when the sizes of the plurality of connection members 30 on the XY-plane are compared with one another, it is necessary to use the same component in each of the connection members 30 or the same parameter related to the size in each of the connection members 30. Note that, in the following description, the “size of the connection member 30 on the XY-plane” is also simply referred to as the “size of the connection member 30”.

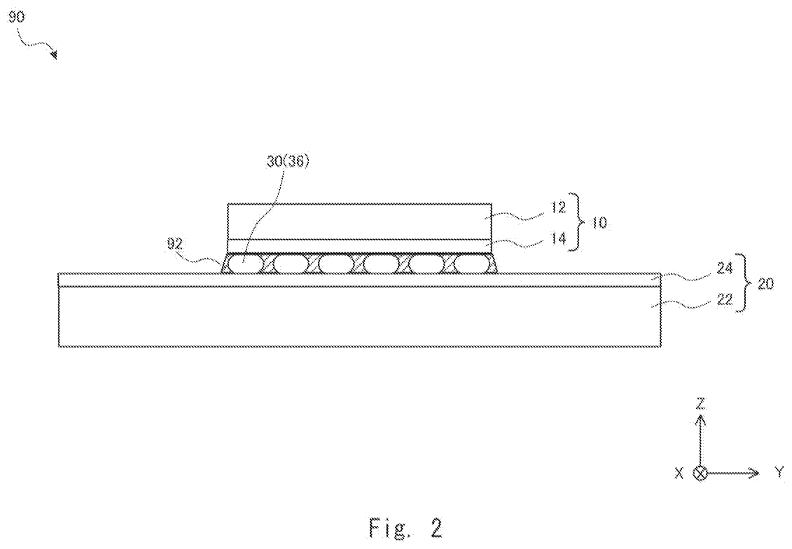

Advantageous effects of the quantum device 1 according to this example embodiment will be described hereinafter by using a comparative example. FIG. 2 shows a configuration of a quantum device 90 according to a comparative example. The quantum device 90 includes a quantum chip 10, and an interposer 20 on which at least one quantum chip 10 is mounted. The quantum chip 10 includes a quantum-chip substrate 12 and a quantum-chip wiring layer 14. The interposer 20 includes an interposer substrate 22 and an interposer wiring layer 24. Further, the quantum chip 10 is connected to the interposer 20 through a plurality of connection members 30 (bumps 36) interposed therebetween. In this way, the quantum chip 10 is flip-chip connected to the interposer 20.

Note that, in the comparative example, the sizes of the plurality of connection members 30 on the XY-plane may be constant (i.e., equal to each other) irrespective of their positions relative to the quantum chip 10. Further, a sealing material 92 such as an underfill agent is provided around the connection members 30. The sealing material is made of, for example, a resin. In this way, the connection members 30 is protected and reinforced by the sealing material 92.

Note that the difference between the coefficient of thermal expansion (hereinafter also referred to as the thermal expansion coefficient) of an organic material such as the sealing material 92 (e.g., a resin material) and that of the components of the quantum device 90, such as the quantum chip 10, the interposer 20, and the connection member 30, is large. Therefore, due to the difference between the amounts of the deformations of them caused by the contraction thereof when the quantum device 90 is cooled to an extremely low temperature, a stress (a thermal stress) or a strain occurs, causing a possibility that the quantum device 90 including the connection members 30 may be fractured. Further, in the case where the sealing material 92 is provided around the connection members 30, since the constraint to the connection members 30 in the direction along the XY-plane is large, there is a possibility that the difference between the amount of the deformation in the direction along the XY-plane and that in the Z-axis direction increases, causing a higher possibility that the quantum device 90 including the connection members 30 may be fractured. Meanwhile, since the quantum device 90 is often used in an environment in which the quantum device 90 is maintained at an extremely low temperature, it is unnecessary to give much consideration to the thermal fatigue (the fatigue caused by repeated deformations) of the connection members 30 which would otherwise be caused when the temperature frequently changes in a short cycle. Therefore, the effect of the protection and the reinforcement of the connection members 30 obtained by the sealing material 92 is small. Further, there is a risk that the sealing material 92 made of an organic material may become brittle and be broken when the quantum device 90 is cooled to an extremely low temperature. Therefore, the sealing material 92 is preferably not provided in the quantum device 90.

Note that, in the case where the sealing material 92 is not provided, an increase in the stress that occurs in the connection member 30 (stress concentration) and an internal stress caused by a strain (a residual stress) resulting from the deformations of members due to contraction (thermal contraction) caused by the decrease in temperature become problematic during the cooling of the quantum device. That is, there is a difference between the thermal expansion coefficients of the components of the quantum device 90 such as the quantum chip 10, the interposer 20, and the connection member 30. Therefore, it is conceivable to reduce the difference between the thermal expansion coefficients by using the same material as the main material for the components. Meanwhile, when the same material is used and hence their temperatures change equally, the length by which the member contracts is in proportion to the length of that member. Therefore, when the sizes of the quantum chip 10 and the interposer 20 are different from each other, the magnitudes (e.g., the lengths) of their contractions due to the cooling are different from each other. In such a case, there is a risk that a stress may occur in the shear direction of the connection member 30 (i.e., the direction along the XY-plane). In particular, since the volume of the connection member 30 is small, there is a possibility that a stress concentration may occur in the direction along the XY-plane. Therefore, it is necessary to increase the strength of the connection member 30 in the direction along the XY-plane.

In contrast to this, in this example embodiment, the size of each of the plurality of connection members 30 on the XY-plane is changed according to the position of that connection member relative to the quantum chip 10. By the above-described configuration, it is possible prevent the connection members 30 from being broken by, in particular, increasing the size on the XY-plane of a connection member(s) 30 that is located in a place(s) where the stress caused by the contractions of components is likely to become high during the cooling.

For example, the quantum chip 10 tends to contract in a direction toward the center (the central point) during the cooling. As a result, the amount of the deformation (or the length of the displacement) due to the contraction becomes large in the outer-peripheral area 40 of the quantum chip 10, which is distant from the center thereof. Therefore, there is a high possibility that stress concentration occurs in the connection member(s) 30 disposed in the outer-peripheral area 40. Therefore, it is possible to prevent the connection members 30 from being broken by increasing the size on the XY-plane of a connection member(s) 30 that is located, in particular, in the outer-peripheral area 40.

Note that in order to increase the strength of the connection members 30, it is also conceivable to increase the sizes of all the connection members 30 connected to the quantum chip 10. Note that in the quantum device 1, the connection members 30 (the bumps 36) may possibly come into contact with the ground electrode. Therefore, in order to suppress the deterioration of the coherence, it is necessary to comply with various design constraints such as a constraint that the ground electrode should not be disposed near the oscillator, a constraint that the impedance of the signal circuit should be matched, and a constraint that the function (the coupling) as the quantum circuit should be controlled. Therefore, if the sizes of all the connection members 30 (all the bumps) are increased, the connection members 30, which are at the ground potential, are disposed close to the oscillator, the signal lines, and the quantum circuit formed in the quantum device 1, so that there is a risk that their characteristics may deteriorate (i.e., may deviate) from the desired characteristics. Therefore, it is not preferable to increase the sizes of all the connection members 30 connected to the quantum chip 10.

### First Example Embodiment

An example embodiment will be described hereinafter with reference to the drawings. The following description and the drawings are partially omitted and simplified as appropriate for clarifying the explanation. Further, the same elements are denoted by the same reference numerals (or symbols) throughout the drawings, and redundant descriptions thereof are omitted as appropriate.

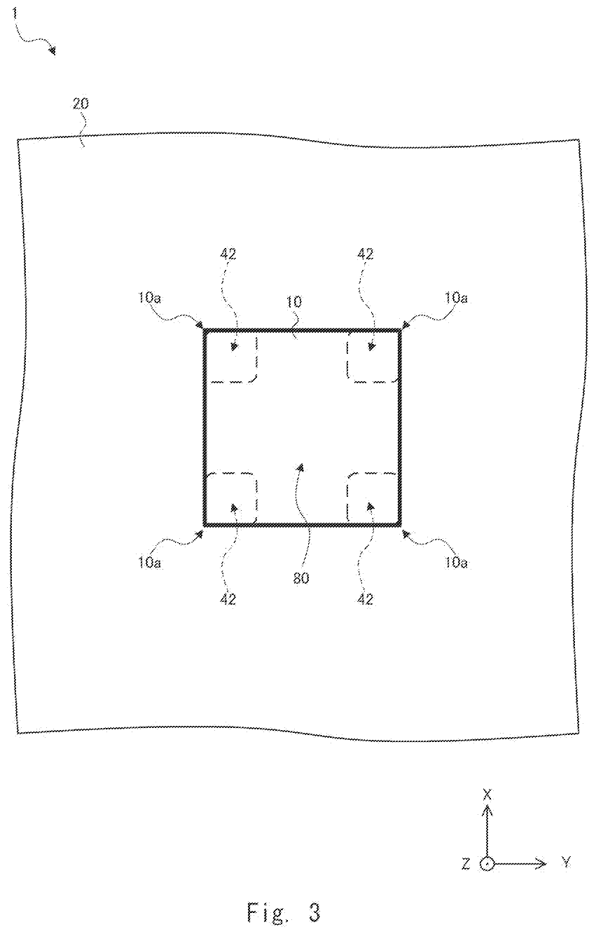

FIG. 3 is a plan view showing a quantum device 1 according to a first example embodiment. In particular, FIG. 3 is a plan view of the quantum device 1 shown in FIG. 1 as viewed from the side of the quantum chip 10 (i.e., from the upper side of FIG. 1). The quantum chip 10 according to the first example embodiment is formed in a square shape (a rectangular shape). As described above, the quantum chip 10 is connected to the interposer 20 with the connection members 30 interposed therebetween.

In the first example embodiment, corner areas 42 each of which corresponds to a respective one of the four corners 10a of the quantum chip 10 correspond to the outer-peripheral area 40 shown in FIG. 1. That is, the outer-peripheral area 40 includes the corner areas 42. The corner areas 42 are areas near the corners 10a. Further, the corner areas 42 may be areas including the corners 10a. Further, in the first example embodiment, the sizes of connection members 30 (bumps 36) connected to the corner areas 42 are larger than the sizes of connection members 30 connected to an area 80 other than the corner areas 42 (the outer-peripheral area 40) of the quantum chip 10. The corner areas 42 may be formed so that, for example, the length of one side of the corner areas 42 is equal to or shorter than one third (⅓) of the length of the one side of the quantum chip 10 parallel to that side, and is preferably equal to or shorter than a quarter (¼) of the length of the one side of the quantum chip 10 parallel to that side.

There is a high possibility that, when the quantum device 1 is cooled to an extremely low temperature, the places in the quantum chip 10 that are displaced by the largest amount due to the contraction of the quantum chip 10 are likely to be the corners 10a, which are farthest from the center of the quantum chip 10. Therefore, large stresses (shear stresses) may occur in the connection members 30 connected to the quantum chip 10 near the corners 10a thereof. Further, since the corners 10a are parts having discontinuous shapes in the quantum chip 10, stress concentrations may occur in the connection members 30 connected to the quantum chip 10 near the corners 10a thereof. Therefore, in order to prevent the connection members 30 from being broken by such large stresses (stress concentrations), the sizes of the connection members 30 connected to the corner areas 42 are increased. Therefore, in the quantum device 1 according to the first example embodiment, it is possible to prevent the connection members 30 from being broken during the cooling.

### Second Example Embodiment

Next, a second example embodiment will be described. The following description and the drawings are partially omitted and simplified as appropriate for clarifying the explanation. Further, the same elements are denoted by the same reference numerals (or symbols) throughout the drawings, and redundant descriptions thereof are omitted as appropriate. The area(s) corresponding to the outer-peripheral area 40 in the second example embodiment is different from that in the first example embodiment.

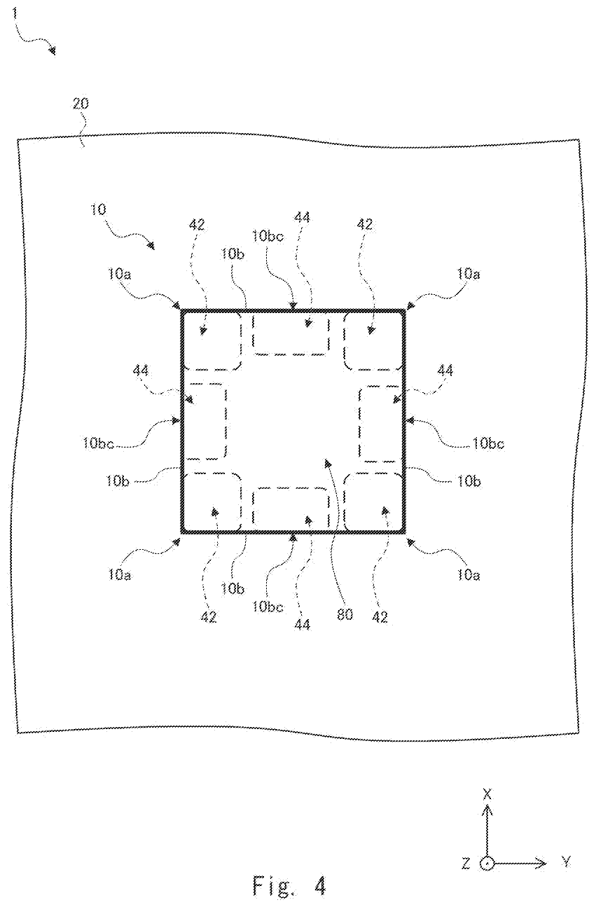

FIG. 4 is a plan view showing a quantum device 1 according to the second example embodiment. In particular, FIG. 4 is a plan view of the quantum device 1 shown in FIG. 1 as viewed from the side of the quantum chip 10 (i.e., from the upper side of FIG. 1). Similarly to the first example embodiment, the quantum chip 10 according to the second example embodiment is formed in a square shape (a rectangular shape). As described above, the quantum chip 10 is connected to the interposer 20 with the connection members 30 interposed therebetween.

In the second example embodiment, the above-described corner areas 42 and a central area 44 in each side (hereinafter also referred to as a side central area 44) correspond to the outer-peripheral area 40 shown in FIG. 1. That is, the outer-peripheral area 40 includes the corner areas 42 and the side central areas 44. The side central areas 44 correspond to central parts 10bc on the sides 10b of the quantum chip 10. For example, the side central areas 44 are areas including the central parts 10bc on the sides 10b of the quantum chip 10. Further, in the second example embodiment, the sizes of connection members 30 (bumps 36) connected to the corner areas 42 or the side central areas 44 are larger than the sizes of connection members 30 connected to an area 80 other than the corner areas 42 and the side central areas 44 (the outer-peripheral area 40) of the quantum chip 10. The corner areas 42 may be formed so that, for example, the length of one side of the corner areas 42 is equal to or shorter than one third (⅓) of the length of the one side of the quantum chip 10 parallel to that side, and is preferably equal to or shorter than a quarter (¼) of the length of the one side of the quantum chip 10 parallel to that side. The side central areas may be formed so that, for example, the length of one side of the side central areas is equal to or shorter than one third (⅓) of the length of the one side of the quantum chip 10 parallel to that side, and is preferably equal to or shorter than a quarter (¼) of the length of the one side of the quantum chip 10 parallel to that side.

When the quantum device 1 is cooled to an extremely low temperature, the deformations due to the contraction of the quantum chip 10 may vary from one place to another in the quantum chip 10 (hereinafter also referred to as variations in deformation). Therefore, in order to make the quantum chip 10 contract uniformly, the sizes of connection members 30 connected to the side central areas 44 as well as to the corner areas 42 are increased. In this way, it is possible to direct the deformation of the quantum chip 10 to the center (e.g., the center of gravity) of the quantum chip 10. Further, in this way, it is possible to prevent or reduce the occurrence of variations in the stress occurring in the connection members 30. Therefore, it is possible to prevent the connection members 30 from being broken due to the increase in the stress (the stress concentration) even further.

Note that, in FIG. 4, the side central area 44 is provided in every one of the four sides 10b. That is, the sizes of the connection members 30 connected to all the side central areas 44 in the four sides 10b are larger than the sizes of the connection members 30 connected to the area 80. However, the side central area 44 does not need to be provided in every one of the four sides 10b. The side central area 44 is preferably provided in at least two opposed sides 10b (the upper and lower sides 10b or the right and left sides 10b in FIG. 4). By arranging the side central areas 44 in this manner, the above-described advantageous effects, which are obtained by providing side central areas 44, can be obtained.

### Third Example Embodiment

Next, a third example embodiment will be described. The following description and the drawings are partially omitted and simplified as appropriate for clarifying the explanation. Further, the same elements are denoted by the same reference numerals (or symbols) throughout the drawings, and redundant descriptions thereof are omitted as appropriate. The shape of the quantum chip 10 in the third example embodiment is different from those in the first and second example embodiments.

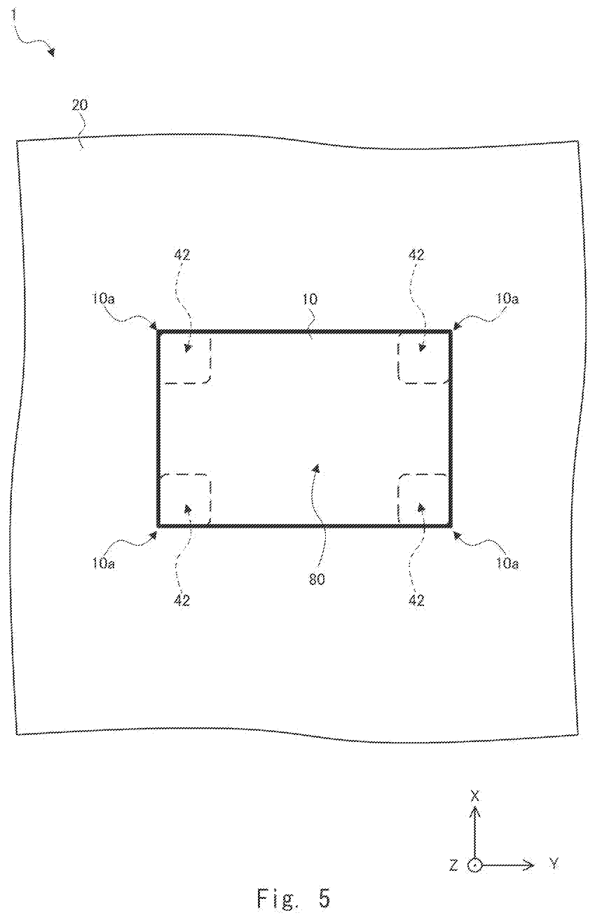

FIG. 5 is a plan view showing a quantum device 1 according to the third example embodiment. In particular, FIG. 5 is a plan view of the quantum device 1 shown in FIG. 1 as viewed from the side of the quantum chip 10 (i.e., from the upper side of FIG. 1). The quantum chip 10 according to the third example embodiment is formed in a rectangle shape (a rectangular shape). That is, the quantum chip 10 according to the third example embodiment is formed so as to have a long-side direction and a short-side direction. The short-side direction may be a direction perpendicular to the long-side direction. As described above, the quantum chip 10 is connected to the interposer 20 with the connection members 30 interposed therebetween.

Similarly to the first example embodiment, corner areas 42 each of which corresponds to a respective one of the four corners 10a of the quantum chip 10 correspond to the outer-peripheral area 40 shown in FIG. 1 in the third example embodiment. Further, in the third example embodiment, the sizes of connection members 30 (bumps 36) connected to the corner areas 42 are larger than the sizes of connection members 30 connected to an area 80 other than the corner areas 42 of the quantum chip 10. The corner areas 42 may be formed so that, for example, the length of one side of the corner areas 42 is equal to or shorter than one third (⅓) of the length of the one side of the quantum chip 10 parallel to that side, and is preferably equal to or shorter than a quarter (¼) of the length of the one side of the quantum chip 10 parallel to that side. Alternatively, the corner areas 42 may be formed so that, for example, the length of one side of the corner areas 42 is equal to or shorter than one third (⅓) of that of the short side of the quantum chip 10, and is preferably equal to or shorter than a quarter (¼) of that of the short side of the quantum chip 10. By the above-described configuration, the quantum device 1 according to the third example embodiment can obtain advantageous effects substantially the same as those in the first example embodiment.

### Fourth Example Embodiment

Next, a fourth example embodiment will be described. The following description and the drawings are partially omitted and simplified as appropriate for clarifying the explanation. Further, the same elements are denoted by the same reference numerals (or symbols) throughout the drawings, and redundant descriptions thereof are omitted as appropriate. The area(s) corresponding to the outer-peripheral area 40 in the fourth example embodiment is different from that in the third example embodiment.

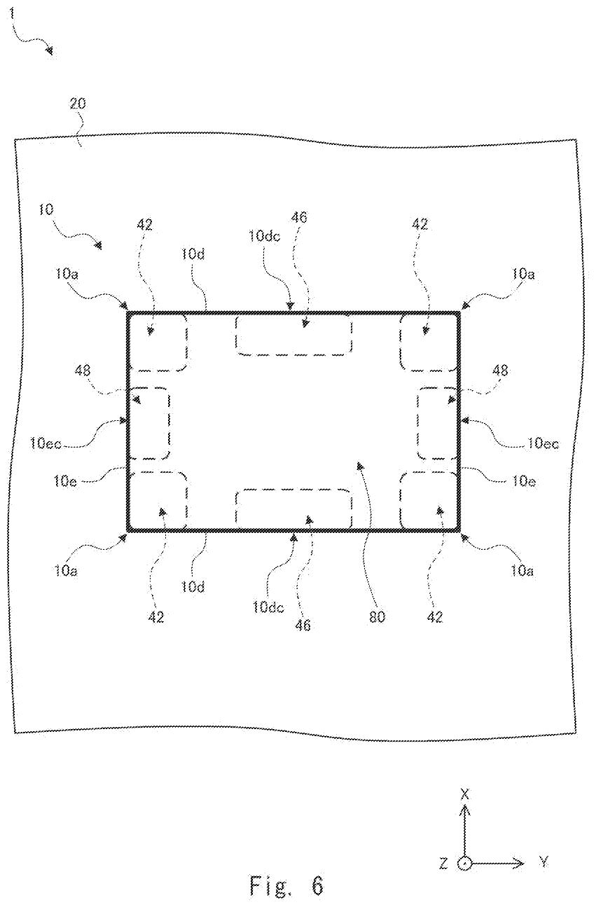

FIG. 6 is a plan view showing a quantum device 1 according to the fourth example embodiment. In particular, FIG. 6 is a plan view of the quantum device 1 shown in FIG. 1 as viewed from the side of the quantum chip 10 (i.e., from the upper side of FIG. 1). Similarly to the first example embodiment, the quantum chip 10 according to the fourth example embodiment is formed in a square shape (a rectangular shape). As described above, the quantum chip 10 is connected to the interposer 20 with the connection members 30 interposed therebetween.

In the fourth example embodiment, the above-described corner areas 42 and side central areas 46 and 48 correspond to the outer-peripheral area 40 shown in FIG. 1. That is, the outer-peripheral area 40 includes the corner areas 42 and the side central areas 46 and 48. The side central areas 46 correspond to central parts 10dc in the long sides 10d of the quantum chip 10. For example, the side central areas 46 are areas including the central parts 10dc in the long sides 10d of the quantum chip 10. Further, the side central areas 48 also correspond to central parts 10ec in the short sides 10e of the quantum chip 10. For example, the side central areas 48 are areas including the central parts 10ec in the short sides 10e of the quantum chip 10. The corner areas 42 may be formed so that, for example, the length of one side of the corner areas 42 is equal to or shorter than one third (⅓) of the length of the one side of the quantum chip 10 parallel to that side, and is preferably equal to or shorter than a quarter (¼) of the length of the one side of the quantum chip 10 parallel to that side. Alternatively, the corner areas 42 may be formed so that, for example, the length of one side of the corner areas 42 is equal to or shorter than one third (⅓) of the length of the short side of the quantum chip 10, and is preferably equal to or shorter than a quarter (¼) of the length of the short side of the quantum chip 10. The side central areas may be formed so that, for example, the length of one side of the side central areas is equal to or shorter than one third (⅓) of the length of the one side of the quantum chip 10 parallel to that side, and is preferably equal to or shorter than a quarter (¼) of the length of the one side of the quantum chip 10 parallel to that side. Alternatively, the side central areas may be formed so that, for example, the length of one side of the side central areas is equal to or shorter than one third (⅓) of the length of the short side of the quantum chip 10, and is preferably equal to or shorter than a quarter (¼) of the length of the short side of the quantum chip 10.

Further, in the fourth example embodiment, the sizes of connection members 30 (bumps 36) connected to the corner areas 42 or the side central areas 46 or 48 are larger than the sizes of connection members 30 connected to the area 80 other than the corner areas 42 and the side central areas 46 and 48 (the outer-peripheral area 40) of the quantum chip 10. By the above-described configuration, the quantum device 1 according to the fourth example embodiment can obtain advantageous effects substantially the same as those in the second example embodiment.

Note that the size (e.g., the superficial measure) of the area of the side central areas 46 and the size (e.g., the superficial measure) of the area of the side central areas 48 may be equal to each other. Alternatively, the size of the area of the side central areas 46 may be larger than the size of the area of the side central areas 48. In such a case, the length of the side central area 46 in the direction along the long side 10d may be larger than the length of the side central area 48 in the direction along the short side 10e. In this way, the range (i.e., the size of the place) in which connection members 30 having large sizes can be disposed is increased in the side central area 46 corresponding to the long side 10d. In this way, it is possible to prevent or reduce the above-described variations in the stress occurring in the connection members 30 even further.

Note that, in FIG. 6, the side central areas 46 are provided in the two opposed long sides 10d, and the side central areas 48 are provided in the two opposed short sides 10e. That is, the sizes of the connection members 30 connected to all the side central areas 46 and 48 in the four sides are larger than the sizes of the connection members 30 connected to the area 80. However, the side central area does not need to be provided in every one of the four sides. The side central area 46 is preferably provided in at least in the long sides 10d. By arranging the side central areas 46 in this manner, the above-described advantageous effects, which are obtained by providing side central areas, can be obtained.

### First Modified Example

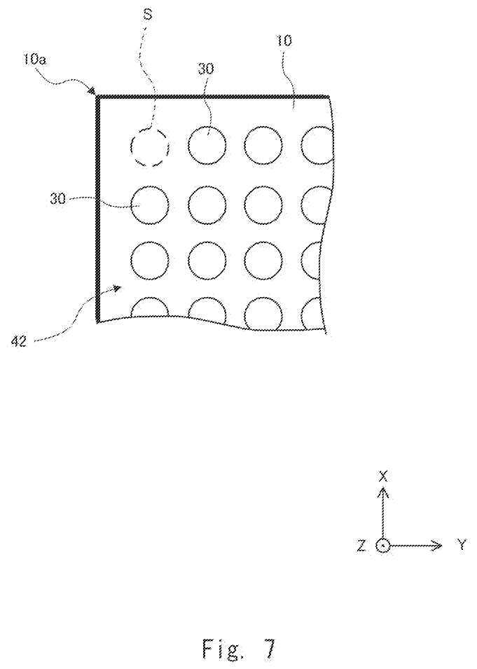

A first modified example of the above-described example embodiment will be described. FIG. 7 shows an example of connection members 30 arranged near a corner 10a of a quantum chip 10 according to the first modified example. Note that this modified example can also be applied to example embodiments described later. The connection member 30 is often arranged in a lattice pattern.

However, in the corner area 42, no connection member 30 may be disposed at a place S closest to the corner 10a. Further, no connection member 30 may be disposed at a place(s) adjacent to the place S. When the connection member 30 is disposed at the place S closest to the corner 10a, a large stress occurs in that connection member 30. Therefore, the connection members 30 may be prevented from being broken by intentionally disposing no connection member 30 at the place S.

### Second Modified Example

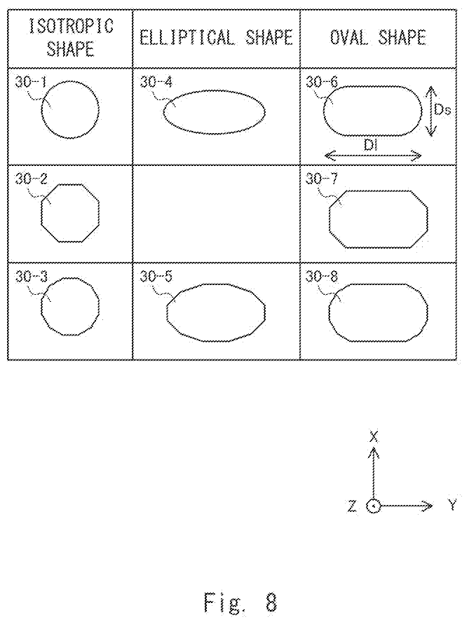

A second modified example of the above-described example embodiment will be described. FIG. 8 is a view showing an example of the shape of a connection member 30 on the XY-plane according to the second modified example. Note that this modified example can also be applied to example embodiments described later. Further, the second modified example may be applied to example embodiments together with the first modified example. The shape of the connection member 30 may be, for example, an isotropic shape, an elliptical shape, or an oval shape. Note that the shape of the bumps 36 on the XY-plane may be roughly determined according to the shapes of the connection terminals 32 and 34. However, depending on the melting point of the bump 36 and the like, the bumps 36 may not have desired shapes on the XY-plane. Therefore, at least the connection terminals 32 and 34 of the connection members 30 may have an isotropic shape, an elliptical shape, or an oval shape as shown in FIG. 8.

Examples of the isotropic shape include a regular circular shape such as a connection member 30-1, a regular octagonal shape such as a connection member 30-2, and a regular dodecagonal shape such as a connection member 30-3. Further, examples of the elliptical shape include an elliptical shape such as a connection member 30-4 and a dodecagonal shape such as a connection member 30-5. Further, examples of the oval shape include a rectangular shape having rounded corners such as a connection member 30-6, an octagonal shape such as a connection member 30-7, and a dodecagonal shape such as a connection member 30-8.

Note that the shape of the connection member 30 preferably has no part having an acute angle which tends to cause a stress concentration. Therefore, the connection member 30 preferably has such a shape that its circumference is formed by a curved line(s) or a straight line(s) as in the case of the connection members 30-1, 30-4 and 30-6. In the case where the circumference cannot be formed by a curved line(s), the connection member 30 preferably has such a shape that the interior angle of the circumference is larger than 90 degrees as in the case of the connection members 30-2, 30-3, 30-5, 30-7 and 30-8.

Note that the connection members 30 having an elliptical shape or an oval shape, i.e., the connection members 30-4 to 30-8, have a long-side direction Dl and a short-side direction Ds. The connection member 30 connected to the outer-peripheral area 40 (the corner area or the side central area) may be formed so as to have a long-side direction and a short-side direction.

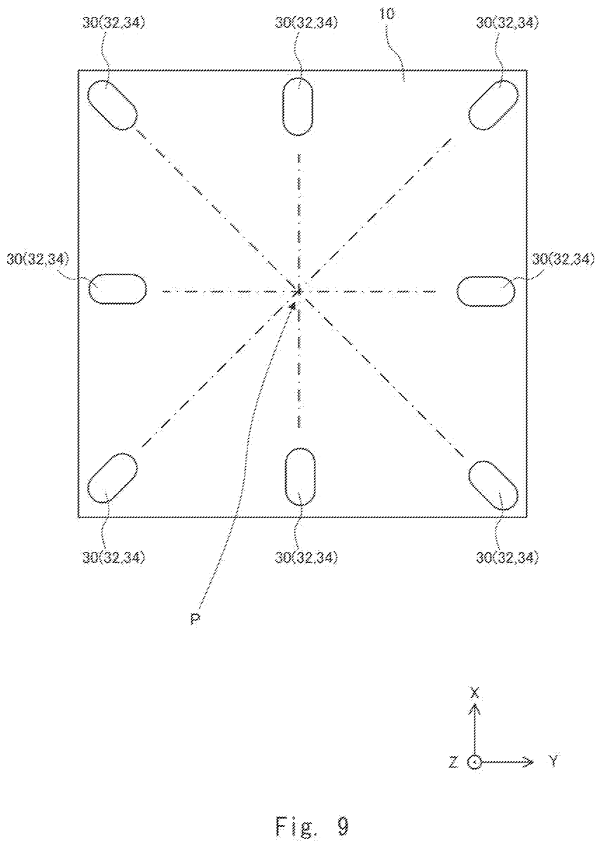

FIG. 9 schematically shows a relation between the orientations of connection members 30 and the position of the quantum chip 10 according to the second modified example. As shown in FIG. 9, connection members 30 each of which has a long-side direction and a short-side direction are arranged so that the long-side directions of the connection members 30 (the connection terminals 32 and 34) are along (e.g., coincide with) straight lines connecting the center P of the quantum chip 10 and the respective centers of the connection members 30 (indicated by dashed lines in FIG. 9). Therefore, in the quantum chip 10, a plurality of connection members 30 are radially arranged around the center of the quantum chip 10. As noted above, the quantum chip 10 contracts along lines pointed toward the center thereof during the cooling. Therefore, in the case where each of a plurality of connection members 30 has a long-side direction and a short-side direction, these connection members 30 are arranged so that their long-side directions are along (i.e., coincide with) the direction toward the center P of the quantum chip 10. As a result, the connection members 30 are disposed so as to be elongated in the contraction direction. Therefore, the strengths of the connection members 30 can be enhanced.

### Fifth Example Embodiment

Next, a fifth example embodiment will be described. The following description and the drawings are partially omitted and simplified as appropriate for clarifying the explanation. Further, the same elements are denoted by the same reference numerals (or symbols) throughout the drawings, and redundant descriptions thereof are omitted as appropriate. The position of the quantum chip 10 relative to the interposer 20 in the fifth example embodiment is different from those in the other example embodiments.

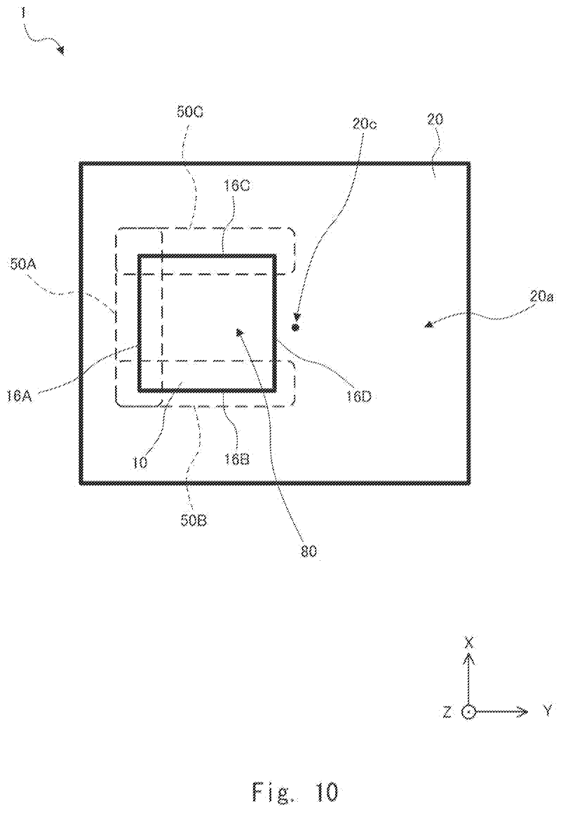

FIG. 10 is a plan view showing a quantum device 1 according to the fifth example embodiment. In particular, FIG. 10 is a plan view of the quantum device 1 shown in FIG. 1 as viewed from the side of the quantum chip 10 (i.e., from the upper side of FIG. 1). In the fifth example embodiment, the quantum chip 10 is not disposed at the center of the interposer 20. That is, in the quantum device 1 according to the fifth example embodiment, the center of the quantum chip 10 does not coincide with the center 20c of the interposer 20.

In this case, in the interposer 20, the deformation of an area 20a where the quantum chip 10 is not mounted is accelerated during the cooling as compared to the deformation of the area where the quantum chip 10 is mounted. As a result, for the connection members 30 connected to the quantum chip 10, a large stress (a larger stress concentration) occurs on the opposite side of the area 20a. That is, since the contraction is restrained in the area where the quantum chip 10 is mounted, the stress(es) occurring in a connection member(s) 30 connected to the periphery of the quantum chip 10 distant from the center 20c of the interposer 20 increases.

Therefore, distant areas 50A, 50B and 50C corresponding to the sides 16A, 16B and 16C, among the four sides of the quantum chip 10, located on the sides distant from the center 20c of the interposer 20 are provided. The distant areas 50 (a first outer-peripheral area) are a part of the above-described outer-peripheral area 40. That is, the outer-peripheral area 40 includes the distant areas 50. In other words, the distant areas 50 correspond to the outer-peripheral area 40. Note that no distant area 50 is provided in the side 16D closest to the center 20c.

Further, the sizes of connection members 30 connected to the distant areas 50 are made larger than the sizes of connection members 30 connected to an area 80 other than the distant areas 50. That is, the sizes of connection members 30 connected to at least a part of the distant areas 50 in the outer-peripheral area 40 of the quantum chip corresponding to the side 16 thereof distant from the center of the interposer 20 is larger than the sizes of connection members 30 connected to the area 80 other than the distant areas 50. By the above-described configuration, it is possible to prevent the connection members 30 connected to the quantum chip 10, whose center does not coincide with the center of the interposer 20, from being broken during the cooling.

### Sixth Example Embodiment

Next, a sixth example embodiment will be described. The following description and the drawings are partially omitted and simplified as appropriate for clarifying the explanation. Further, the same elements are denoted by the same reference numerals (or symbols) throughout the drawings, and redundant descriptions thereof are omitted as appropriate. The sixth example embodiment is different from the other example embodiments because a plurality of quantum chips 10 are mounted in the interposer 20 in the sixth example embodiment.

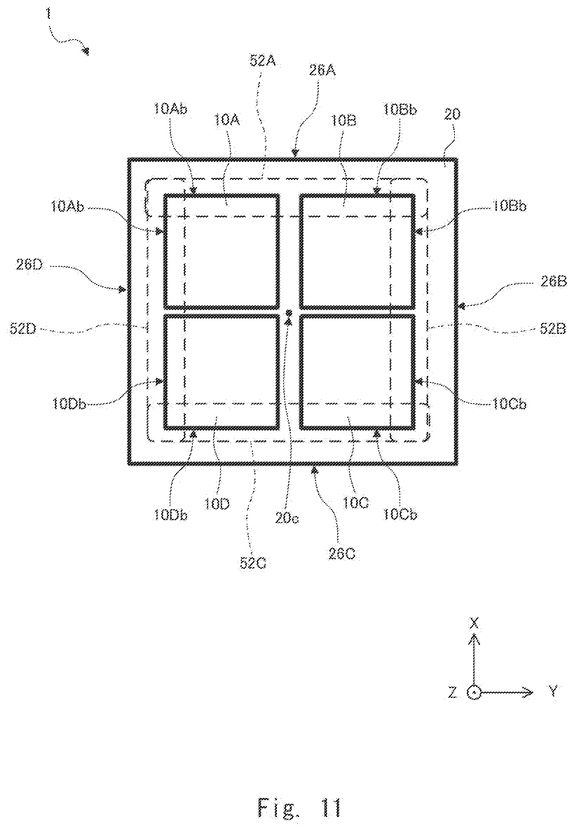

FIG. 11 is a plan view showing a quantum device 1 according to the sixth example embodiment. In particular, FIG. 11 is a plan view of the quantum device 1 shown in FIG. 1 as viewed from the side of the quantum chip 10 (i.e., from the upper side of FIG. 1). In the sixth example embodiment, a plurality of quantum chips 10A, 10B, 10C and 10D are mounted in the interposer 20. Note that although four quantum chips 10 are mounted in the interposer 20 in the example shown in FIG. 11, the number of quantum chips 10 mounted on the interposer 20 may be any number equal to or larger than two.

Note that, similarly to the quantum chip 10, the amount of the deformation (or the length of the displacement) due to the contraction becomes large in the outer periphery 26 of the interposer 20 distant from the center 20c thereof during the cooling. Therefore, there is a possibility that a large stress (a large stress concentration) occurs in the connection members 30 connected to a quantum chip 10 (a first quantum chip) mounted near the outer periphery 26 of the interposer 20. Therefore, the sizes of connection members 30 connected to at least a part of the outer-peripheral area 40 of the quantum chip 10 (the first quantum chip) mounted near the outer periphery 26 is made larger than the sizes of connection members 30 connected to quantum chips 10 other than the aforementioned quantum chip 10. In this way, it is possible to prevent the connection members 30 from being broken due to the contraction of the interposer 20.

More specifically, for the quantum chips 10A and 10B (first quantum chips) mounted near an outer periphery 26A of the interposer 20, an outer-peripheral area 52A (a second outer-peripheral area) corresponding to their respective sides 10Ab and 10Bb close to the outer periphery 26A is provided. Similarly, for the quantum chips 10B and 10C (first quantum chips) mounted near an outer periphery 26B of the interposer 20, an outer-peripheral area 52B (a second outer-peripheral area) corresponding to their respective sides 10Bb and 10Cb close to the outer periphery 26B is provided. Further, for the quantum chips 10C and 10D (first quantum chips) mounted near the outer periphery 26C of the interposer 20, an outer-peripheral area 52C (a second outer-peripheral area) corresponding to their respective sides 10Cb and 10Db close to the outer periphery 26C is provided. Further, for the quantum chips 10D and 10A (first quantum chips) mounted near the outer periphery 26D of the interposer 20, an outer-peripheral area 52D (a second outer-peripheral area) corresponding to their respective sides 10Db and 10Ab close to the outer periphery 26D is provided.

In this case, the sizes of connection members 30 connected to the outer-peripheral areas 52A, 52B, 52C and 52D are made larger than the sizes of connection members 30 connected to the areas other than the outer-peripheral areas 52A, 52B, 52C and 52D. Note that, as described above, the amount of the deformation (or the length of the displacement) due to the contraction becomes large in the outer periphery 26 of the interposer 20 distant from the center 20c thereof during the cooling. Therefore, by increasing the sizes of the connection members 30 connected to the outer-peripheral area 52 near the outer periphery 26 of the quantum chip 10, it is possible to prevent the connection members 30 from being broken even when a large stress occurs in these connection members 30.

Note that, similarly to the above-described first example embodiment and the like, the sizes of the connection members 30 connected to the areas corresponding to all the outer peripheries (i.e., the outer-peripheral areas 40) of the quantum chips 10A, 10B, 10C and 10D may be increased. Meanwhile, since the size of the interposer 20 is larger than the size of the quantum chip 10, the amount of contraction of the interposer 20 during the cooling is larger than that of the quantum chip 10. Therefore, regarding the whole quantum device 1, the effect of the contraction during the cooling may be the largest near the outer periphery 26 of the interposer 20. Therefore, it is possible to prevent the connection members 30 from being broken more effectively by making the sizes of the connection members 30 connected to the outer-peripheral area 52 corresponding to the outer periphery 26 of the interposer 20 larger than the sizes of the connection members 30 connected to the areas other than the outer-peripheral area 52.

### Seventh Example Embodiment

Next, a seventh example embodiment will be described. The following description and the drawings are partially omitted and simplified as appropriate for clarifying the explanation. Further, the same elements are denoted by the same reference numerals (or symbols) throughout the drawings, and redundant descriptions thereof are omitted as appropriate. The area(s) to which a connection member(s) 30 having a large size is connected in the seventh example embodiment is different from those in the other example embodiments.

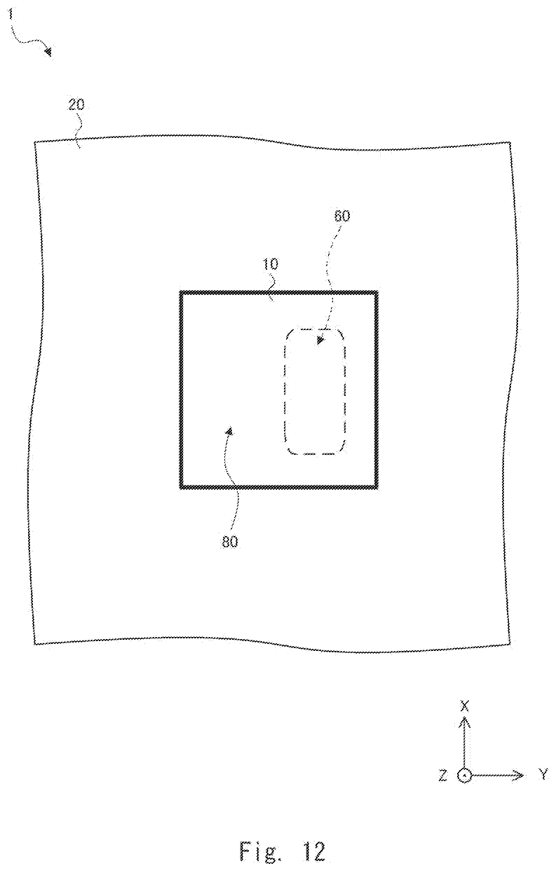

FIG. 12 is a plan view showing a quantum device 1 according to a seventh example embodiment. In particular, FIG. 12 is a plan view of the quantum device 1 shown in FIG. 1 as viewed from the side of the quantum chip 10 (i.e., from the upper side of FIG. 1). As described above, the quantum chip 10 is connected to the interposer 20 through connection members 30.

The quantum chip 10 generates heat as its quantum circuit operates. Further, it is assumed that the amount of heat generated in a heat-generating area 60 is higher than that of the other area(s) 80 in the quantum chip 10. Further, in the seventh example embodiment, the sizes of connection members 30 connected to at least a part of the heat-generating area 60 is made larger than the sizes of connection members 30 connected to the area 80 other than the heat-generating area 60.

When heat is generated in the quantum chip 10, the heat-generating area 60 may expand. Meanwhile, the other area 80 contracts due to the cooling. Therefore, the thermal stress may increase in the heat-generating area 60. Therefore, in order to prevent or reduce such an increase in thermal stress, it is desirable to reduce the unevenness of the temperature. To that end, it is possible to dissipate (or radiate) the heat in the heat-generating area 60 through the connection members 30 connected to the heat-generating area 60 by increasing the sizes of these connection members 30. Further, it is possible to increase the strength of the connection members 30 at a position where the thermal stress is likely to increase, by increasing the sizes of the connection members 30 connected to the heat-generating area 60. Therefore, it is possible to prevent the connection members 30 from being broken due to the thermal stress.

### Eighth Example Embodiment

Next, an eighth example embodiment will be described. The following description and the drawings are partially omitted and simplified as appropriate for clarifying the explanation. Further, the same elements are denoted by the same reference numerals (or symbols) throughout the drawings, and redundant descriptions thereof are omitted as appropriate. The orientations in which the connection members 30 are disposed in the eighth example embodiment are different from those in other example embodiments.

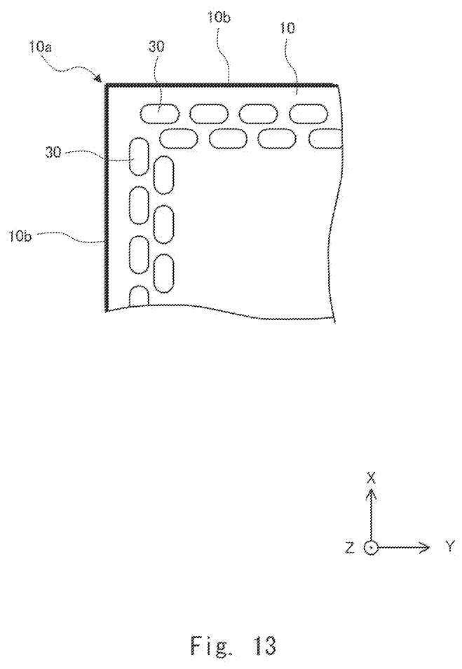

FIG. 13 is a plan view showing a quantum chip 10 according to the eighth example embodiment. FIG. 13 shows an area of the quantum chip 10 near a corner 10a thereof. Note that, in the eighth example embodiment, the shape of each of the connection members 30 is an elliptical shape or an oval shape as shown in FIG. 8. Therefore, the connection member 30 has a long-side direction and a short-side direction. Further, the connection members 30 are arranged such that their long-side directions are along (i.e., parallel to) the directions of the sides 10b (outer edges) of the quantum chip 10.

Further, a plurality of connection members 30 are arranged in a plurality of rows along the sides 10b. Further, the plurality of connection members 30 are arranged in a staggered manner so that each of connection members 30 in a given row is disposed next to the space between two connection members 30 adjacent to each other arranged in the next row. That is, the plurality of connection members 30 are arranged in a lattice pattern (a checkered pattern).

As the plurality of connection members 30 are arranged in this manner, when viewed from the outside of the quantum chip 10, the inside area is shielded by these connection members 30. Further, as described above, the ground electrode is formed near the outer periphery of the quantum chip 10. Accordingly, the plurality of connection members 30 can function as a ground shield. That is, the plurality of connection members 30 can shield the quantum circuit disposed inside the quantum chip 10 from magnetic noises which would otherwise enter therein from the outside of the quantum chip 10. In general, a quantum circuit is very sensitive to magnetism, and is sensitive to and may react to, for example, even the presence of very weak magnetism such as terrestrial magnetism, causing the quantum circuit to malfunction (i.e., causing the deterioration of quantum coherence). Further, there are various magnetic noises other than the terrestrial magnetism in the environment in which the quantum circuit is operated. Therefore, by arranging a plurality of connection members 30 near the outer periphery of the quantum chip 10 as in the case of the eighth example embodiment, it is possible to prevent the quantum circuit provided (i.e., formed) in the quantum chip 10 from malfunctioning as well as preventing the connection members 30 from being broken due to the stress. Note that although an example in which the connection members 30 having the identical shapes are arranged in two rows is shown in FIG. 13, the shape and the arrangement of the connection members 30 are not limited to those shown in the above-shown example. The connection members 30 having different shapes may be used and the number of rows thereof may be changed as long as the connection members 30 can shield the inside of the quantum chip 10.

### Modified Example

Note that the present disclosure is not limited to the above-described example embodiments and various modifications can be made within the scope and spirit of the present disclosure. For example, the above-described example embodiments are applicable to one another. For example, the first example embodiment (FIG. 3) and the fifth example embodiment (FIG. 10) can be applied to each other. In such a case, the connection members 30 connected to the area where the corner area 42 overlaps with the distant area 50 may have the largest sizes. Further, the connection members 30 connected to an area in the distant area 50 which does not overlap with the corner area 42 may have the second largest sizes, i.e., have the size that is smaller than the sizes of the connection members 30 connected to the area where the corner area 42 overlaps with the distant area 50 but is larger than the sizes of connection members 30 connected to the other areas. Further, the sizes of connection members 30 that are connected to neither the corner area 42 nor the distant area 50 may have the smallest sizes. The same applies to the case where one of the second, third and fourth example embodiments and the fifth example embodiment are applied to each other, and to the case where one of the first, second, third and fourth example embodiments and the sixth example embodiment are applied to each other. Even in these cases, the sizes of connection members 30 connected to the area where the areas corresponding to the outer-peripheral areas 40 (the corner areas 42, the side center areas 44 and 46, the distant area 50, the outer-periphery area 52, and the like) overlap with each other are also made larger than the sizes of connection members 30 in the area(s) where the aforementioned areas do not overlap with each other. In this way, it is possible to prevent the connection members 30 from being broken during the cooling in a more appropriate manner.

Further, although the sizes of connection members 30 connected to the corner area 42 and the side central area 44 are increased in the second example embodiment (FIG. 4), the configuration according to the second example embodiment is not limited to such a configuration. The sizes of only the connection members 30 connected to the side central area 44 may be increased. That is, no corner area 42 may be provided in the second example embodiment. The same applies to the fourth example embodiment (FIG. 6).

The first to eighth example embodiments can be combined as desirable by one of ordinary skill in the art.

While the disclosure has been particularly shown and described with reference to embodiments thereof, the disclosure is not limited to these embodiments. It will be understood by those of ordinary skill in the art that various changes in form and details may be made therein without departing from the spirit and scope of the present disclosure as defined by the claims.

The whole or part of the example embodiments disclosed above can be described as, but not limited to, the following supplementary notes.

(Supplementary Note 1)

A quantum device comprising:
at least one quantum chip; and
at least one interposer in which the at least one quantum chip is mounted; and
a plurality of connection members each of which is formed of a conductor, the plurality of connection members being disposed between the quantum chip and the interposer so as to connect the quantum chip with the interposer, wherein
a size of each of the plurality of connection members on a surface along a mounting surface of the interposer is changed according to a position of that connection member relative to the quantum chip, the mounting surface being a surface on which the quantum chip is mounted.

(Supplementary Note 2)

The quantum device described in Supplementary note 1, wherein a size of the connection member connected to at least a part of an outer-peripheral area corresponding to an outer periphery of the quantum chip is larger than a size of the connection member connected to an area other than the outer-peripheral area of the quantum chip.

(Supplementary Note 3)

The quantum device described in Supplementary note 2, wherein
the outer-peripheral area includes a corner area corresponding to a corner of the quantum chip, and
a size of the connection member connected to at least the corner area is larger than a size of the connection member connected to an area other than the outer-peripheral area of the quantum chip.

(Supplementary Note 4)

The quantum device described in Supplementary note 2 or 3, wherein
the outer-peripheral area includes a side central area corresponding to a center of a side of the quantum chip, and
a size of the connection member connected to at least the side central area is larger than a size of the connection member connected to an area other than the outer-peripheral area of the quantum chip.

(Supplementary Note 5)

The quantum device described in Supplementary note 4, wherein
the quantum chip is formed in a rectangular shape, and
sizes of the connection members connected to side central areas corresponding to at least two opposed sides, respectively, of the quantum chip are larger than a size of the connection member connected to an area other than the outer-peripheral area of the quantum chip.

(Supplementary Note 6)

The quantum device described in Supplementary note 4, wherein
the quantum chip is formed so as to have a long-side direction and a short-side direction, and
a size of the side central area corresponding to a side along the long-side direction of the quantum chip is larger than a size of the side central area corresponding to a side along the short-side direction of the quantum chip.

(Supplementary Note 7)

The quantum device described in any one of Supplementary note 2 to 6, wherein the connection member located in at least the outer-peripheral area is formed so as to have a long-side direction and a short-side direction.

(Supplementary Note 8)

The quantum device described in Supplementary note 7, wherein the connection member having the long-side direction and the short-side direction is disposed so that the long-side direction of the connection member is along a straight line connecting a center of the quantum chip with a center of that connection member.

(Supplementary Note 9)

The quantum device described in Supplementary note 2, wherein
for the quantum chip in which a center of the quantum chip does not coincide with the center of the interposer, in the outer-peripheral area of the quantum chip, a size of the connection member connected to at least a part of a first outer-peripheral area corresponding to a side of the interposer distant from a center thereof is larger than a size of the connection member connected to an area other than the first outer-peripheral area of the quantum chip.

(Supplementary Note 10)

The quantum device described in Supplementary note 2, wherein
a plurality of quantum chips are mounted in the interposer, and
a size of the connection member connected to at least a part of the outer-peripheral area of a first quantum chip mounted near the outer periphery of the interposer is larger than a size of the connection member connected to the quantum chip other than the first quantum chip.

(Supplementary Note 11)

The quantum device described in Supplementary note 10, wherein a size of the connection member connected to a second outer-peripheral area corresponding to a side of the outer-peripheral area of the first quantum chip close to the outer periphery of the interposer is larger than a size of the connection member connected to an area other than the second outer-peripheral area of the first quantum chip.

(Supplementary Note 12)

The quantum device described in Supplementary note 1, wherein a size of the connection member connected to at least a part of a heat-generating area of the quantum chip in which a larger amount of heat is generated than those in other areas of the quantum chip is larger than a size of the connection member connected to an area other than the heat-generating area of the quantum chip.

(Supplementary Note 13)

The quantum device described in any one of Supplementary notes 1 to 12, wherein the connection member comprises a first connection terminal formed in the quantum chip, a second connection terminal formed in the interposer, and a bump connecting the first connection terminal with the second connection terminal.

(Supplementary Note 14)

The quantum device described in any one of Supplementary notes 1 to 13, wherein a size of each of the plurality of connection members on a surface along the mounting surface is a cross-sectional area of the connection member, a length of an outer circumference of the connection member, or a length in a longitudinal direction of the connection member.

What is claimed is:

1. A quantum device comprising:
at least one quantum chip; and
at least one interposer in which the at least one quantum chip is mounted; and
a plurality of connection members each of which is formed of a conductor, the plurality of connection members being disposed between the quantum chip and the interposer so as to connect the quantum chip with the interposer, wherein
a size of each of the plurality of connection members on a surface along a mounting surface of the interposer is changed according to a position of that connection member relative to the quantum chip, the mounting surface being a surface on which the quantum chip is mounted.

2. The quantum device according to claim 1, wherein a size of the connection member connected to at least a part of an outer-peripheral area corresponding to an outer periphery of the quantum chip is larger than a size of the connection member connected to an area other than the outer-peripheral area of the quantum chip.

3. The quantum device according to claim 2, wherein
the outer-peripheral area includes a corner area corresponding to a corner of the quantum chip, and
a size of the connection member connected to at least the corner area is larger than a size of the connection member connected to an area other than the outer-peripheral area of the quantum chip.

4. The quantum device according to claim 2, wherein
the outer-peripheral area includes a side central area corresponding to a center of a side of the quantum chip, and
a size of the connection member connected to at least the side central area is larger than a size of the connection member connected to an area other than the outer-peripheral area of the quantum chip.

5. The quantum device according to claim 4, wherein
the quantum chip is formed in a rectangular shape, and
sizes of the connection members connected to side central areas corresponding to at least two opposed sides, respectively, of the quantum chip are larger than a size of the connection member connected to an area other than the outer-peripheral area of the quantum chip.

6. The quantum device according to claim 4, wherein
the quantum chip is formed so as to have a long-side direction and a short-side direction, and
a size of the side central area corresponding to a side along the long-side direction of the quantum chip is larger than a size of the side central area corresponding to a side along the short-side direction of the quantum chip.

7. The quantum device according to claim 2, wherein the connection member located in at least the outer-peripheral area is formed so as to have a long-side direction and a short-side direction.

8. The quantum device according to claim 7, wherein the connection member having the long-side direction and the short-side direction is disposed so that the long-side direction of the connection member is along a straight line connecting a center of the quantum chip with a center of that connection member.

9. The quantum device according to claim 2, wherein
for the quantum chip in which a center of the quantum chip does not coincide with the center of the interposer, in the outer-peripheral area of the quantum chip, a size of the connection member connected to at least a part of a first outer-peripheral area corresponding to a side of the interposer distant from a center thereof is larger than a size of the connection member connected to an area other than the first outer-peripheral area of the quantum chip.

10. The quantum device according to claim 2, wherein
a plurality of quantum chips are mounted in the interposer, and
a size of the connection member connected to at least a part of the outer-peripheral area of a first quantum chip mounted near the outer periphery of the interposer is larger than a size of the connection member connected to the quantum chip other than the first quantum chip.

11. The quantum device according to claim 10, wherein a size of the connection member connected to a second outer-peripheral area corresponding to a side of the outer-peripheral area of the first quantum chip close to the outer periphery of the interposer is larger than a size of the connection member connected to an area other than the second outer-peripheral area of the first quantum chip.

12. The quantum device according to claim 1, wherein a size of the connection member connected to at least a part of a heat-generating area of the quantum chip in which a larger amount of heat is generated than those in other areas of the quantum chip is larger than a size of the connection member connected to an area other than the heat-generating area of the quantum chip.

13. The quantum device according to claim 1, wherein the connection member comprises a first connection terminal formed in the quantum chip, a second connection terminal formed in the interposer, and a bump connecting the first connection terminal with the second connection terminal.

14. The quantum device according to claim 1, wherein a size of each of the plurality of connection members on a surface along the mounting surface is a cross-sectional area of the connection member, a length of an outer circumference of the connection member, or a length in a longitudinal direction of the connection member.
